(19) United States
(12) Patent Application Publication
(10) Pub. No.: US 2007/0155132 A1
(43) Pub. Date: Jul. 5, 2007

(54) Method of manufacture for a component including at least one single-crystal layer on a substrate

(76) Inventors: Michel Ancilotti, Nort Sur Erdre (FR); Pierre Tauzinat, Paris (FR); Frederic Lainat, Ligne (FR); Olivier Briere, Barbechat (FR); Olivier Carriot, Coueron (FR); Gerard Gadot, Treillieres (FR)

Correspondence Address: RATNERPRESTIA, P O BOX 980, VALLEY FORGE, PA, 19482-0980, US

(21) Appl. No.: 11/633,707

(22) Filed: Dec. 5, 2006

(30) Foreign Application Priority Data
Dec. 9, 2005 (FR) 05 12527

(51) Int. Cl. H01L 21/30; H01L 21/20

(52) U.S. Cl. 438/459; 438/479; 438/509; 438/507

(57) ABSTRACT

The invention refers to a method of manufacture for a component including a single-crystal substrate on which is deposed at least one single-crystal layer, the method including one or several steps for single-crystal layers' deposit by pulverisation of a metal or of semi-conductors inside a plasma of gas, and the method being characterised in that the rate of atom deposit is lower than the homogenisation rate of such atoms among themselves.

This invention concerns a method of manufacture for a component including a superposition of one or several single-crystal layers on a substrate, also single-crystal. The single-crystal layers are layers of silicon and/or germanium, or even insulating layers, notably made of silicon oxide. Thus, the method of manufacture enables, for example, to manufacture a component comprising a single-crystal silicon substrate on which is deposited an insulating layer, on which is superposed a layer of silicon and/or germanium, notably single-crystal.

Such method also enables to manufacture a component comprising a single-crystal silicon substrate on which is deposited a layer of silicon, also single-crystal.

In another application, a component is manufactured, characterised in that the substrate is a single-crystal insulator, composed of a metal oxide or of semi-conductors, on which is deposited, for example, a layer of single-crystal silicon and/or germanium.

The metal or semi-conductors' oxide is, in an embodiment, an insulator such as quartz or sapphire.

The substrates composed of the silicon on isolator (SOI) type are used in the manufacture of advanced integrated circuits (nano and micro-electric), but also for the manufacture of discontinuous semi-conductor components, or of micro-systems MEMS. One of the main advantages of using a SOI substrate in relation to a Silicon substrate, is improved insulation for the transistors of the integrated circuits (less leakage current), which is demonstrated by a reduced energy consumption. This insulation gain is due, particularly, to the dielectric layer interposed between a support substrate and the active single-crystal Silicon layer. The integrated circuits based on the SOI are also adapted to use in severe conditions (Temperature, Radiations).

Among the numerous techniques proposed for the manufacture of silicon plates on insulator, the “SmartCut™” technology and the “SIMOX” technology can be quoted.

The SmartCut™ technology has today become the industrial standard for manufacturing SOI substrates. Such technique consists of creating a fragile zone, by implanting hydrogen in a single-crystal silicon substrate thermally oxidized on the surface. The material (Substrate A) thus constituted is associated via molecular adhesion on a second substrate B thermally oxidized in advance. After mechanical cleavage, eased by the existence of the fragile zone in the substrate A, a SOI substrate composed of three layers (Si—SiO2-Si) is obtained. It is then necessary to thin down the superficial layer of silicon, and this is performed by a mechano-chemical polishing.

Such method is quite complex and costly, and requires a full set of tools. Furthermore, such technique is limited for the thinnest thicknesses of the superficial silicon layer (called “active”) and of the oxide layer (called “BOX”). Indeed, for the thinnest thicknesses, the unevenness of the thickness on the diameter of the substrate, due to the polishing step, is a limitative factor for the semi-conductor components embodied using substrates.

The SIMOX technology, as for that, consists of implanting oxygen O⁺ ions at the heart of a single-crystal silicon substrate, in order to directly create a Silicon/Oxide stacking of silicon/Silicon.

Thus, the oxygen ions pass through the upper substrate layer in order to reach the insulating layer. The major inconvenience of this technology is that the passage of the oxygen ions introduces defects in the oxide layer and in the upper layer of silicon. It is thus necessary to carry out several annealing processes in order to reduce such defects, defects which cannot be entirely eliminated.

Furthermore, such technique is known not to be well adapted to the embodiment of SOI substrates representing a very thin Silicon active layer, and/or a very thin Sio2 layer (BOX).

Consequently, such technique is not used for composed substrates dedicated to the latest generations of semi-conductor technologies.

Such technique necessitates the use of specific equipment and considerable energy consumption.

The invention aims at resolving at least one of these inconveniences, by proposing a method enabling to manufacture an almost perfect stacking within a single enclosure.

Another embodiment concerns a method of composed substrate manufacture comprising a single-crystal insulating substrate on which is deposited a layer of silicon and/or single-crystal germanium. The insulating substrate is, for example, composed of Quartz (SiO₂ silica crystal shape), or of another type of metal oxide or semi-conductors' oxide having optical characteristics and/or selected electric insulation.

This type of composed substrate is generally appreciated for its transparency properties in terms of what can be seen, and further for its excellent electric insulation properties. Micro or nanoelectronic components can be embodied on such substrates for the purpose of manufacturing integrated circuits destined for various applications including optoelectronics (Flat screens, sensors of the CCD type, CMOS imagers) photon and communication (radio frequency RF or high frequency HF).

Such type of composed substrate is generally manufactured by using the Smart-Cut™ technology. Such technology, mainly used to embody SOI substrates, consists of associating by adhesion a circular plate of silicon and/or single-crystal germanium transferred onto a circular plate in silica of the same diameter. The limitations associated to this technique for manufacturing the SOQ originate from the materials' thermal expansion coefficient differences.

By using the Smart-Cut technology, the transfer of the silicon and/or germanium layer imposes a certain thickness for this layer.

The invention aims at proposing a new method of manufacture, enabling to embody high quality substrates through a simple and low-cost method within a single enclosure. Such process further enables to embody extremely thin single-crystal silicon and/or germanium layers.

The invention thus concerns the manufacture of a component including a single-crystal substrate on which is deposed at least one single-crystal layer, the method including one or several steps for single-crystal layer deposit by pulverisation of a metal or of a semi-conductor inside a gas plasma, and the method being characterised in that the rate of atom deposit is lower than the homogenisation rate of such atoms among themselves. The deposit rate is thus comprised between 2 and 10 nm/min.

Such a method, due to the deposit rate being rather slow, enables to embody a low-temperature expitaxy, namely between 350° C. and 500° C. In fact, in the state of the technical art, particularly in the methods of the deposit type via chemical vapour (CVD: Chemical Vapour Deposition), such epitaxies are embodied at temperatures nearing the metals' or the semi-conductors' fusion point, for example, at around 1,000° C. In this case, due to such high temperature, during one of the steps of the method, the dopants existing in the layer, on which the deposit is made, are distributed again inside the pulverised metal or the semi-conductor, for example, silicon. In such a case, there is a retro-distribution phenomena giving rise to poor electric junctions, and to defects at interface level. Furthermore, due to such distribution, the layer deposited is not homogeneous, for example, in terms of the dopants' concentration.

On the contrary, in the method described here, the temperature of the deposit is much lower, which has the effect of dividing the dopants' distribution rate by 30 or 40 in relation to the existing techniques. Consequently, the manufactured components represent abrupt electrical junctions, almost without defect, and homogeneous layers.

Furthermore, such slow deposit speed enables to perfectly control the thickness of the deposited metal or semi-conductor or insulator, i.e. the thickness of the epitaxy. Thus can be obtained a precision similar to an atomic layer.

In an application, such method can be used to manufacture a component comprising a single-crystal silicon substrate on which is deposited an insulating layer, on which is superposed a layer of silicon and/or germanium, such method including the following steps:
during a first step, silicon is pulverised, onto a single-crystal silicon plate, a metal or a semi-conductor or an insulator into an oxygen and argon plasma, thus creating an oxide layer on the plate in order to create the insulating layer, then
during a second step, silicon and/or germanium is pulverised via plasma onto such oxide layer.

In a more general manner, according to the embodiments, the single-crystal material from the single-crystal substrate is included in the group comprising silicon, germanium and a material rich in silicon isotope 28, the Si28.

The method is, for example, such that all the steps are embodied in a same vacuum enclosure, in whish is found the substrate whereon shall be performed the deposits, in addition to the metal, semi-conductor or insulating targets destined to be pulverised.

According to the embodiments, the method of manufacture comprises different steps, and enables the manufacture of various component types:

In a first example, the method is such that the substrate is a single-crystal silicon substrate, and the method includes a step for single-crystal silicon deposit.

In this case, the component obtained comprises two layers of single-crystal silicon, each one having electrical characteristics which can be different. Such a component shall be described in detail below.

Such method of manufacture can also be applied in the case where the silicon is replaced by germanium or by a combination of both.

In a second example, the method is such that the substrate is a single-crystal silicon substrate and the method includes two steps for deposit:
a first step during which silicon is pulverised into an argon and oxygen plasma, thus creating a single-crystal silicon oxide film, and
a second step during which silicon is pulverised into argon plasma, thus creating a single-crystal silicon oxide film.

In this case, the component manufactured is a component of the SOI type (Silicon on Insulator).

This method of manufacture is also applicable for the manufacture of a Germanium on Insulator component.

In a third example, the method is such that the substrate is a metal or semi-conductor oxide substrate, insulating, and the method includes a step for single-crystal silicon and/or germanium deposit. (For example, Silicon On Quartz (SOQ)).

In another embodiment, the material deposed during a step is a semi-conductor material included in the group comprising: silicon, germanium, and a material rich in silicon isotope 28: the Si28.

Depending on whether is pulverised, during a deposit step, only silicon, only germanium, or the two products simultaneously, the component created shall be, respectively, of the SOI, GeOI or SiGeOI.

The gases introduced inside the enclosure for the purpose of creating the plasma differ according to the pulverisation step performed.

Thus, in an embodiment, the plasma used during a deposit step is argon or oxygen plasma. In such a case, the layer deposited is a metal or semi-conductor oxide insulating layer.

In another embodiment, the plasma used during a deposit step is an argon plasma, the layer deposed thus being a single-crystal metal or of semi-conductor layer.

In this case, can be, for example, injected simultaneously oxygen and argon during the first step, then the oxygen injection stopped when passing to the second step.

In an embodiment, in order to obtain that the deposit atoms' rate is lower than the homogenisation rate of these same atoms among themselves, the plasma production source is controlled by different means than those used to control the polarisation of the targets serving for the different pulverisations, particularly by a different electrode than the targets or than the substrate holder.

Thus, there is a decoupling process between, on the one hand, the creation of ions serving for the pulverisation and, on the other hand, polarisation of the targets, such polarisation determining the pulverisation output. Such decoupling enables to vary the homogenisation rate by sending polarised ions onto the oxide layer so that they lose their kinetic force upon impact on such layer, thus enabling to increase the mobility of the deposited atoms.

In an embodiment, the plasma used is an inductive plasma, i.e. created by an external aerial, for example emitting in a frequency range from 0.1 to 100 MHz, across a dielectric.

Thus can be created a plasma of the ICP type (inductive coupling plasma), or of the TCP type (transforming coupling plasma). In this manner, the geometry of the aerial can be chosen from among several configurations, so as to select the one ensuring the most homogenous plasma.

Furthermore, the fact of using an external aerial enables to reduce the risks of metallic contamination from the plasma due to parasites from the aerial and/or from the dielectric. Thus, it is also useful, in an embodiment, to use a dielectric in a non-metallic material, such as glass.

In an embodiment, the targets used for the pulverisations are polarised by using a polarisation included in the group comprising: a polarisation of the radio frequency (RF) type, a polarisation in direct current (DC) or a polarisation in pulsating direct current.

In this last case, it is essential that each voltage pulse has a positive voltage swing in order to maintain the pulverisation on the semi-conductor and insulating materials. The polarisation in pulsed direct current (DC) enables to stabilise the cathode sputtering, this, in particular, for low-conducting materials. The RF polarisation being, in its case, adapted for insulating materials.

In one of the embodiments, the first step of the method described above consists of depositing an oxide layer on a single-crystal silicon substrate. Generally, the substrate used consists of a silicon plate available on the market, and which is therefore protected by an oxide. In this case, but also in other embodiments, it is useful to add to the method a preliminary step consisting of removing the oxide existing on the substrate, notably on a plate of single-crystal silicon. In order to do so, a known method, for example, of chemical cleaning shall be used, such as the RCA cleaning, developed by the “Radio Corporation of America”. In another embodiment, the cleaning is performed by a rapid annealing process (RTP) over a time varying from 30 seconds to 5 minutes.

This preliminary step can also be performed in other preferred embodiments of the invention.

Furthermore, it is also useful, once the component finalised, i.e. once all the deposits performed, to deposit a protective layer on the external surface of the component. Thus, in an embodiment, the method includes a final step consisting of depositing, on the upper layer, a passivation layer destined to protect the component. Such layer, also called “barrier layer”, enables to prevent the passage of impurities able to affect the quality of the silicon and/or germanium on insulator component.

The upper layer is, for example, a layer of single-crystal silicon or germanium.

The various methods to embody such a passivation layer are already known in the art. For example, the passivation layer is performed by pulverising silicon and/or germanium into a hydrogen plasma. Such possibility has the advantage of not necessitating any specific equipment, as it will use a neighbouring method to the one employed for depositing the silicon and/or germanium oxide layers.

Another solution consists of directly introducing atomic hydrogen in the form of gas, and not in the plasma phase. In this case, the hydrogen directly reacts with the silicon and/or the germanium in order to form passivation hydride liaisons.

In the case where the process is used to embody a component of the SOI type, and in order for the method of manufacture to be the most simple and as less costly as possible, it is useful that the metal or the semi-conductor pulverised during all of the steps is, in an embodiment, silicon. Thus, it is enough to have only a single pulverisation target for embodying the various deposits. In this case, the oxide created to create the insulating layer is silicon oxide.

The component created in this configuration includes a silicon/oxide stacking for silicon/silicon and/or germanium, which is the most commonly used stacking today, in the integrated circuit industry.

On the other hand, silicon oxide, having a very low permittivity, with a dielectric constant K equal to 3.9, it is necessary, so that the component created has an acceptable electricity power, for the insulating layer to be very thin without, however, enabling the current to pass. However, the embodiment of such layers, for example, a thickness less than 50 nanometres, is relatively complex, as it is necessary that the silicon surface is completely covered over to prevent considerable loss of current. It is thus necessary to proceed with an extremely precise and meticulous manufacture.

One solution to resolve such inconvenience consists, in an embodiment during which a metal or semi-conductor oxide is deposited, in order to create an oxide having high permittivity, for example, where the dielectric constant k is comprised between 15 and 30.

Such oxides having a higher permittivity, it is possible to embody thicker layers, while maintaining a good electric capacity; the manufacturing process is easier, thus leading to better quality layers.

Furthermore, silicon oxide represents, in relation to silicon, a relatively important mesh discrepancy of approximately 9.5%. Such mesh discrepancy results in a more difficult priming for the epitaxy used in order to allow the single-crystal silicon and/or germanium increase on the substrate. Furthermore, the silicon/oxide interfaces represent many structural defects.

In order to improve the crystallinity of such interfaces, it is useful, in an embodiment, to create, during the first step, an oxide so that the mesh discrepancy between such oxide and the silicon and/or germanium is lower than 6%.

Thus, according to the chosen embodiment, the oxide created is included in the group comprising: lanthanum aluminate (LaAlO₃), zirconium oxide (ZrO₂) stabilised by yttrium oxide, Y₂O₃ (YZS), and cerium oxide (CeO₂).

The quantity of yttrium oxide existing in zirconium oxide is generally just several percent, for example 8%.

Such different oxides represent the two characteristics mentioned above, as they all have a high permittivity, and their mesh discrepancies with silicon are respectively worth 1.2%, 5.35% and 0.35%.

The method of manufacture described above is such that it enables the embodiment of a relatively large silicon on insulator and/or germanium on insulator and/or silicon-germanium on insulator component. For example, in an embodiment, the component created has a disk shape and a diameter equal to or exceeding 50 millimetres.

Such component serves as a basis for manufacturing integrated circuits by silicon and/or germanium dopant.

In order to ensure good quality circuits, it is necessary to ensure the proper stabilisation of the layers deposited and constituting the manufactured component. To this effect, in an embodiment, the method includes one or several annealing steps.

The invention also concerns a component having the same characteristics as those of a component manufactured by a method of the above type.

Other characteristics and advantages of the invention will be shown in the description of preferred embodiments, such description being backed up by sketches on which:

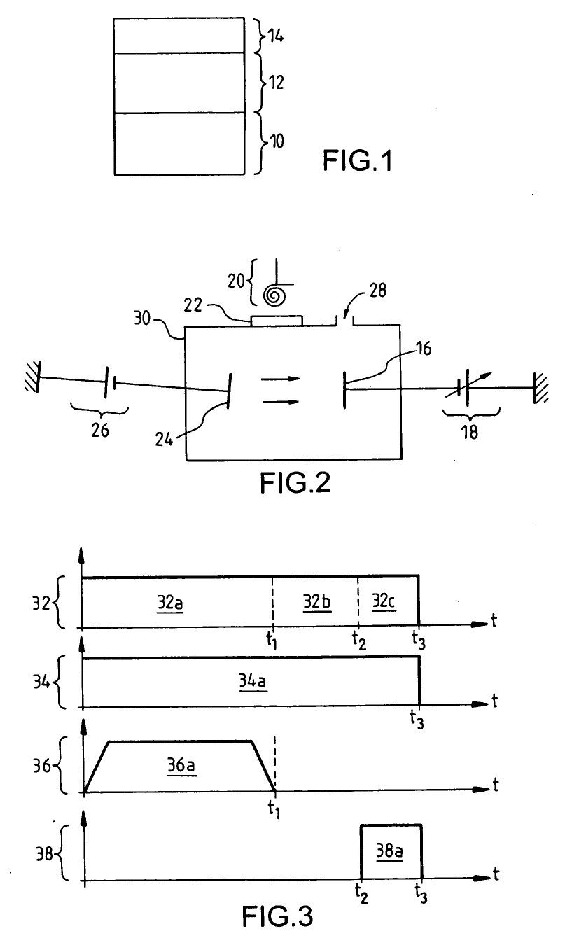

FIG. 1 represents a component embodied by using a method complying with the invention,

FIG. 2 represents a system enabling to embody a component using a method complying with the invention, and

FIG. 3 represents a timing chart of the various steps of a method complying with the invention,

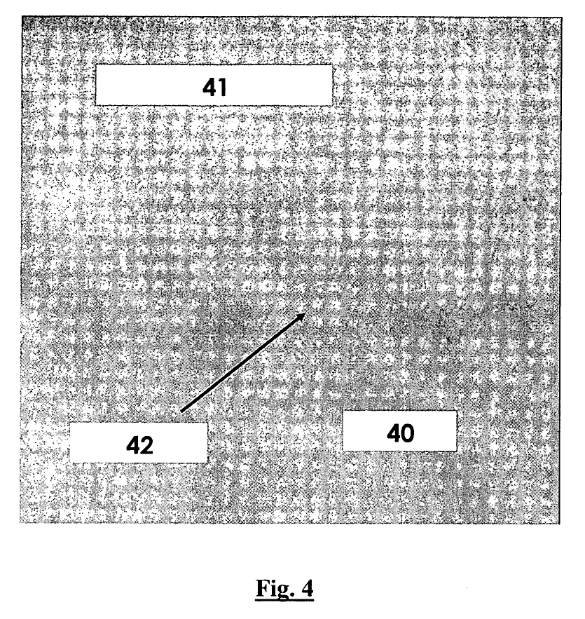

FIG. 4 represents an example of Silicon stacking on silicon, carried out according to a method complying with the invention.

FIG. 1 shows, as a section, a component obtained by a method of manufacture complying with the invention, such component having a disk shape of a diameter equal to or exceeding 50 mm.

Such component comprises a single-crystal silicon substrate 10, such as, for example, a silicon plate available on the market. The oxide on such plate is cleaned off beforehand. Furthermore, the component comprises an insulating layer 12 constituted of an oxide deposited by plasma pulverisation, such as silicon oxide (SiO2), lanthanum aluminate (LaAlO₃), zirconium oxide (ZrO₂) stabilised by yttrium oxide, Y₂O₃ (YZS), or even cerium oxide (CeO₂). Such layer 12 has a thickness of 300 nanometres.

The last layer 14 is a single-crystal silicon and/or germanium layer deposited by plasma pulverisation, which has a thickness of 100 nanometres.

In the case where the last layer is a single-crystal silicon layer, such silicon can be doped.

The manufacture of this component is performed in a vacuum enclosure 30, such as represented in FIG. 2. The pressure in such enclosure is, for example, around 0.1 to 1 Pa.

In the enclosure 30 can be found a single-crystal silicon substrate, in the shape of a silicon plate 16. Such silicon plate serves as a base to receive deposits destined to create the different layers of the component. The plate 16 is linked up to a means 18 for regulating the temperature so that such temperature does not exceed 600° C. during manufacture.

In a more precise manner, the temperature of the substrate is generally maintained between 375 and 450° C. In an example, the method is such that the temperature of the substrate can be reduced below 300° C.

The plasma production device comprises a radio frequency aerial 20 and a dielectric plan 22, embodied in a non-metallic material, such as glass, in order to prevent any metallic contamination of the plasma by the surfaces. In another embodiment, a helical aerial, rolled around a dielectric tube, can be used.

In this case, the component created shall be a silicon/oxide on silicon/silicon stacking. To this effect, the enclosure 30 only comprises a single-crystal silicon target 24. In order to embody other stackings, one or several metal or semi-conductor or insulating targets should be installed inside the enclosure, in order to correspond to the oxide desired.

Such target 24 is embodied using means for polarisations 26, which are independent from the plasma production means 20 and 22. In an example, the target is polarised with a pulsed direct current generator, of the “pulsed DC” type.

In order to carry out the deposits of the various layers by plasma, gases (28) shall be successively introduced according to a sequence defined in advance.

An example of sequence is shown in FIG. 3. Such figure illustrates 4 time charts respectively showing the different steps of the method of manufacture (time chart 32), the sequence of introducing Argon gas into the enclosure (time chart 34), the sequence of introducing oxygen into the enclosure (time chart 36), and the sequence of introducing hydrogen into the enclosure (time chart 38).

The first step represented (32a) is the step for depositing a silicon oxide layer on a silicon substrate 16. To this effect, argon (34a) and oxygen (36a) are introduced into the enclosure 30 and transformed into plasma using the means 20 and 22.

The chemical reaction taking place between the oxygen ions and the silicon vapour, mainly resulting from pulverisation of the target 24 by the argon ions, has the effect of creating silicon oxide SiO during the transport of silicon into the plasma.

When such oxide reaches the substrate 16, the atoms are rearranged in order to form silicon oxide SiO2. At the t1 instance, an insulating layer is deposited according to the desired thickness; thus it is necessary to pass to the next step (32b) in the method of manufacture.

Thus, the introduction of oxygen into the enclosure 30 is stopped and only argon shall remain.

Such argon enables to pulverise, by plasma, the target 24 silicon in order to deposit a layer of single-crystal silicon onto the insulating layer deposited previously.

The t2 instance indicates the end of the pure silicon depositing step. The component is thus finished.

However, it is useful to deposit, during a step 32c, an additional layer, called “passivation layer”.

Such layer, destined to protect the component from corrosion, is embodied by introducing atomic hydrogen into the enclosure (38a) which reacts with the atoms on the outer surface of the silicon and/or germanium in order to create the silicon-hydrogen and/or germanium-hydrogen passivating liaisons.

Once the method is terminated, at the instance t3, the introduction of hydrogen into the enclosure is stopped.

The total time for embodying the method can vary from 1 minute 30 to 15 minutes depending on the deposit rates chosen.

The silicon deposit rate is, for example, comprised between 250 nm/min for a micro-crystal deposit, and 2 to 10 nm/min for a single-crystal deposit.

Thus, as described above, a method according to the invention can be used to embody different types of components, particularly components comprising a single-crystal silicon layer deposited on a single-crystal silicon substrate.

FIG. 4 shows an example of such component, observed using an electronic microscope with transmission.

In this figure can be seen a single-crystal silicon substrate 40 on which a layer 41, or eptitaxy, of single-crystal silicon is made to grow, via plasma pulverisation. The layer 41 and the substrate 40 are separated by an interface 42.

The electrical characteristics of the two layers can be different due to, for example, it being possible to have a substrate with a resistance of 5 to 10 ohms per centimetre, and to make an epitaxial silicon layer increase in size, with a resistance of around 100 ohms per centimetre. According to the embodiments, the silicon deposited during the method can be completed by dopants, of the N type or of the P type.

In this figure, it can be clearly seen that the silicon atoms deposited by pulverisation have been rearranged and homogenised in order to create a perfect layout with the atoms of the substrate.

1. A Method of manufacture for a component including a single-crystal substrate on which is deposed at least one single-crystal layer, the method being characterised in that it includes one or several steps for single-crystal layers' deposit by pulverisation of a metal or of semi-conductors inside a plasma of gas, and in that the rate of atom deposit is lower than the homogenisation rate of the atom among themselves.

2. A method according to claim 1 characterised in that the targets used for the pulverisations are polarised using a polarisation included in the group comprising: a polarisation (26) of the direct current (DC) type or pulsating direct current, or radio frequency (RF).

3. A method according to claim 1, characterised in that the single-crystal material for the single-crystal substrate is included in the group comprising: Silicon, Germanium, and a material rich in silicon isotope 28, the Si28.

4. A method according to claim 1 characterised in that the material deposed during a step is a semi-conductor material included in the group comprising: silicon, germanium, and a material rich in silicon isotope 28, the Si28.

5. A method according to claim 1, characterised in that the plasma used during a step is plasma of argon and of oxygen, a layer deposed thus being an insulating layer of metal or semi-conductors' oxide.

6. A method according to claim 1, characterised in that the plasma used during a step is plasma of argon, the layer deposed thus being a single-crystal metal or semi-conductors' layer.

7. A method according to claim 1 in which the substrate is a single-crystal silicon substrate, and the method includes a step for single-crystal silicon deposit.

8. A method according to claim 1 characterised in that it includes an insulating single-crystal layer deposit of metal or semi-conductors' oxide, on a semi-conductors' single-crystal substrate.

9. A method according to claim 1 in which the substrate is a single-crystal silicon substrate, and the method includes two steps for deposit:
a first step during which silicon is pulverised into an argon and oxygen plasma, thus creating a single-crystal silicon oxide layer, and
a second step during which silicon is pulverised into an argon plasma, thus creating a single-crystal silicon layer.

10. A method according to claim 1 in which the single-crystal substrate is a metal or semi-conductors' oxide substrate, insulating such as, for example, quartz or sapphire, the method including a step for silicon and/or germanium single-crystal deposit.

11. A method according to claim 1, characterised in that the plasma used is an inductive plasma, i.e. created by an external aerial (20) through a dielectric (22).

12. A method according to claim 11 characterised in that the plasma production source is independently controlled by the polarisation of the targets serving for the different pulverisations, particularly by a different electrode than the targets or than the substrate holder.

13. A method according to claim 11 characterised in that the external aerial (20) emits in a frequency range starting from 0.1 up to 100 MHz.

14. A method according claim 1 including the preliminary step of removing the oxide present on the plate of single-crystal silicon.

15. A method according to claim 1 including the final step of manufacture for a layer of passivation destined to protect the component.

16. A method according to claim 15, characterised in that the layer of passivation is performed by pulverising silicon and/or germanium into a hydrogen plasma.

17. A method according to claim 1 characterised in that, when a layer of oxide is deposited, the oxide created is an oxide having a dielectric constant k is comprised between 15 and 30.

18. A method according to claim 1 characterised in that the oxide created during the first step of pulverisation is such that the mesh discrepancy between such oxide and the silicon and/or germanium is lower than 6%.

19. A method according to claim 1 in which the oxide created is included in the group comprising: lanthanum aluminate (LaAlO₃), zirconium oxide (ZrO₂) stabilised by yttrium oxide, Y₂O₃ (YZS), and cerium oxide (CeO₂).

20. A method according to claim 1, characterised in that it includes one or several steps for annealing, enabling a stabilization of the layers deposited.

21. A method according to claim 1 characterised in that the component created has a disk shape and a diameter equal to or exceeding 50 millimetres.

22. A component having the same specifications as those of a component manufactured by a process conform to claim 1.
